(19) United States
(12) Patent Application Publication
(10) Pub. No.: US 2009/0032871 A1
(43) Pub. Date: Feb. 5, 2009

(54) INTEGRATED CIRCUIT WITH INTERCONNECTED FRONTSIDE CONTACT AND BACKSIDE CONTACT

(76) Inventors: Louis Vervoort, Pielenhofen (DE); Joachim Mahler, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/832,451

(22) Filed: Aug. 1, 2007

(51) Int. Cl. H01L 23/52; H01L 21/00; H01L 29/76

(52) U.S. Cl. 257/341; 257/691; 438/113; 257/E23.141; 257/E29.226

(57) ABSTRACT

An integrated circuit includes a substrate including an active area, a first metal contact contacting a frontside of the active area, a second metal contact contacting a backside of the active area, and a wafer-level deposited metal structure positioned adjacent to an edge of the active area and interconnecting the first and second contacts.

### BACKGROUND

Wafer level packaging (WLP) methods address the limitations of traditional packaging techniques. “Wafer level package” is to be understood as meaning that the entire packaging and all the interconnections on the wafer as well as other processing steps are carried out before the singulation (dicing) into chips (dies). With WLP, one can simultaneously package all the chips on a single substrate (e.g., wafer) cost-effectively. The singulated chips are then mounted directly on a substrate.

Some types of devices create additional packaging problems or issues, such as a “vertical” device, having terminals on opposite faces of the chip. For example, a vertical power MOSFET typically has a gate terminal and a source terminal on a frontside of the chip and a drain terminal on the backside of the chip. Similarly, other types of integrated circuits (ICs) can also be fabricated in a vertical configuration, such as a vertical diode. Existing processes for producing a wafer level package for vertical devices, however, are relatively complex and expensive.

### SUMMARY

One embodiment provides an integrated circuit. The integrated circuit includes a substrate including an active area, a first metal contact contacting a frontside of the active area, a second metal contact contacting a backside of the active area, and a wafer-level deposited metal structure positioned adjacent to an edge of the active area and interconnecting the first and second contacts.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross-sectional view of one embodiment of a semiconductor device.

FIG. 2A illustrates a cross-sectional view of one embodiment of a semiconductor wafer.

FIG. 2B illustrates a cross-sectional view of one embodiment of semiconductor devices after sawing the semiconductor wafer.

FIG. 3A illustrates a cross-sectional view of one embodiment of a semiconductor wafer.

FIG. 3B illustrates a cross-sectional view of one embodiment of the semiconductor wafer after etching trenches in the semiconductor wafer.

FIG. 3C illustrates a cross-sectional view of one embodiment of the semiconductor wafer after depositing a frontside metal layer.

FIG. 3D illustrates a cross-sectional view of one embodiment of the semiconductor wafer after etching the frontside metal layer.

FIG. 3E illustrates a cross-sectional view of one embodiment of the semiconductor wafer after depositing a packaging material layer.

FIG. 3F illustrates a cross-sectional view of one embodiment of the semiconductor wafer after thinning the wafer backside.

FIG. 3G illustrates a cross-sectional view of one embodiment of the semiconductor wafer after depositing backside metal contacts.

FIG. 3H illustrates a cross-sectional view of one embodiment of the semiconductor wafer after thinning the packaging material layer.

FIG. 4A illustrates a cross-sectional view of one embodiment of the semiconductor wafer after depositing a frontside metal layer on the frontside surface of the wafer.

FIG. 4B illustrates a cross-sectional view of one embodiment of the semiconductor wafer after etching the frontside metal layer.

FIG. 4C illustrates a cross-sectional view of one embodiment of the semiconductor wafer after etching trenches into the semiconductor wafer.

FIG. 4D illustrates a cross-sectional view of one embodiment of the semiconductor wafer after forming metal interconnection structures in the trenches.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

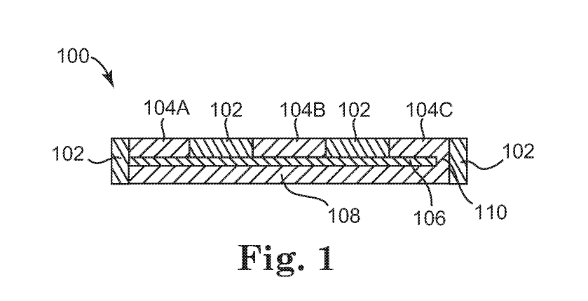

FIG. 1 illustrates a cross-sectional view of one embodiment of an integrated circuit or semiconductor device 100. Semiconductor device 100 includes packaging material 102, frontside metal contacts 104a-104c (collectively referred to as frontside metal contacts 104), active area 106, backside metal contact 108, and metal interconnection structure 110. Frontside metal contacts 104 contact the frontside of active area 106. Backside metal contact 108 contacts the backside of active area 106. Frontside metal contact 104c is connected to backside metal contact 108 via interconnection structure 110, which is positioned adjacent to the edges of active area 106 and contacts 104c and 108. Active area 106 includes transistors, diodes, or other suitable devices formed in a silicon substrate or other suitable substrate. Packaging material 102 laterally surrounds frontside metal contacts 104 and backside metal contact 108 and encapsulates active area 106.

In one embodiment, semiconductor device 100 is a thinned vertical power transistor, and contact 104a is a gate contact of the transistor, contact 104b is a source contact of the transistor, and contacts 104c and 108 are drain contacts of the transistor. The drain contact for a vertical power transistor, such as contact 108, is typically located on the backside of the device. By using interconnection structure 110, contacts 104c and 108 are connected together, and gate, source, and drain contacts 104 are all provided on the frontside of the device 100, which simplifies the connection of device 100 to another device or substrate. In another embodiment, semiconductor device 100 is a different type of device, such as a vertical diode or other type of device. It will be understood by persons of ordinary skill in the art that the number of contacts of device 100 will vary depending upon what type of device it is.

In one embodiment, semiconductor device 100 is encapsulated with packaging material 102 by using a gas phase deposition process, such as a chemical vapor deposition (CVD) process. The gas phase deposition process is fully compatible with front end processes. The packaging material can be applied to several wafers simultaneously, which provides high throughput and lower process costs compared to a mould process. The packaging material can be applied in thin layers (e.g., less than 100 μm); therefore the material costs are low.

Packaging material 102 provides a high insulating capacity and intrinsic layer adhesion due to the molecular gas phase deposition process. The entire encapsulation process flow is performed in-situ. Since the entire encapsulation process flow is performed in-situ, the contamination risk is reduced compared to a mould encapsulation process. In addition, the gas phase deposition process can be performed at room temperature. Therefore, there is no thermal-mechanical stress on the semiconductor device at room temperature if the coefficient of thermal expansion (CTE) of packaging material 102 is not adjusted to the CTE of the silicon of the semiconductor chip.

In one embodiment, packaging material 102 is a plasmapolymer. In one embodiment, the plasmapolymer is a Parylene, such as Parylene C, Parylene N, or Parylene D. Parylene C provides a useful combination of chemical and physical properties plus a very low permeability to moisture, chemicals and other corrosive gases. Parylene C has a melting point of 290° C. Parylene N provides high dielectric strength and a dielectric constant that does not vary with changes in frequency. Parylene N has a melting point of 420° C. Parylene D maintains its physical strength and electrical properties at higher temperatures. Parylene D has a melting point of 380° C.

In another embodiment, packaging material layer 102 includes an amorphous inorganic or ceramic carbon type layer. The amorphous inorganic or ceramic carbon type layer has an extremely high dielectrical breakthrough strength and a coefficient of thermal expansion (CTE) of about 2-3 ppm/K, which is very close to the CTE of silicon of about 2.5 ppm/K. Therefore, the thermal-mechanical stress between the silicon and packaging material layer 102 is low. In addition, the amorphous inorganic or ceramic carbon type layer has a temperature stability up to 450-500° C.

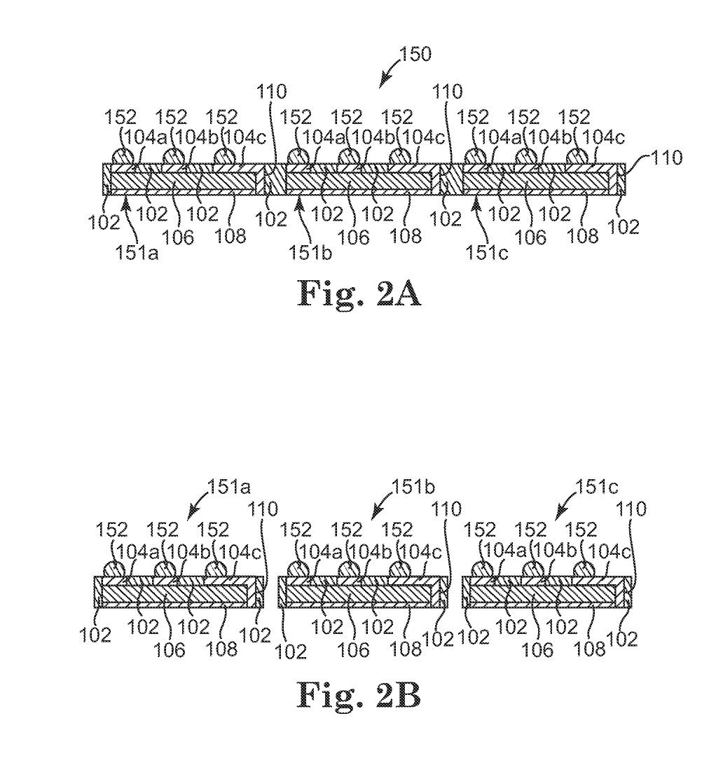

FIG. 2A illustrates a cross-sectional view of one embodiment of a semiconductor wafer 150. Semiconductor wafer 150 includes dies 151a-151c. Each die 151a-151c includes packaging material 102, solder balls 152, frontside metal contacts 104a-104c (collectively referred to as metal contacts 104), active areas 106, backside metal contacts 108, and metal interconnection structures 110. For each die 151a-151c, frontside metal contacts 104 contact the frontside of active area 106; backside metal contact 108 contacts the backside of active area 106; and frontside metal contact 104c is connected to backside metal contact 108 via interconnection structure 110, which is positioned adjacent to the edges of active area 106 and contacts 104c and 108. Active area 106 includes transistors, diodes, or other suitable devices formed in a silicon substrate or other suitable substrate. Packaging material 102 laterally surrounds frontside metal contacts 104 and backside metal contact 108 and encapsulates active area 106. Solder balls 152 contact frontside metal contacts 104.

Solder balls 152 are applied to frontside metal contacts 104 at the wafer level. Interconnection structures 110 are also formed at the wafer level. Due to the wafer-level formation of structures 110 and wafer-level application of the solder balls 152, production costs are minimized. With the solder balls 152 applied at the wafer level, the semiconductor chips can be completely manufactured at the wafer level, which improves throughput. In addition, chip-scale packages (CSPs) are obtained that use a minimum of space. After separating the die, the individual die or chips can be mounted directly onto a circuit board using flip-chip bonding.

FIG. 2B illustrates a cross-sectional view of one embodiment of semiconductor chips 151a-151c after sawing semiconductor wafer 150. Semiconductor wafer 150 is sawed into individual semiconductor chips 150a-150c. By using packaging material 102, very small packages are provided. The packaging material 102 and the backside metallization 108 provide protection against humidity and mechanical stress. If packaging material 102 is selected to have an identical CTE as the semiconductor chip, the semiconductor chip does not experience thermal stress. In addition, the backside metallization 108 also provides efficient cooling on the backside of the semiconductor chips. Further, the semiconductor chips 151a-151c include a short lead length due to the flip-chip design, which is particularly advantageous for power or radio frequency (RF) applications.

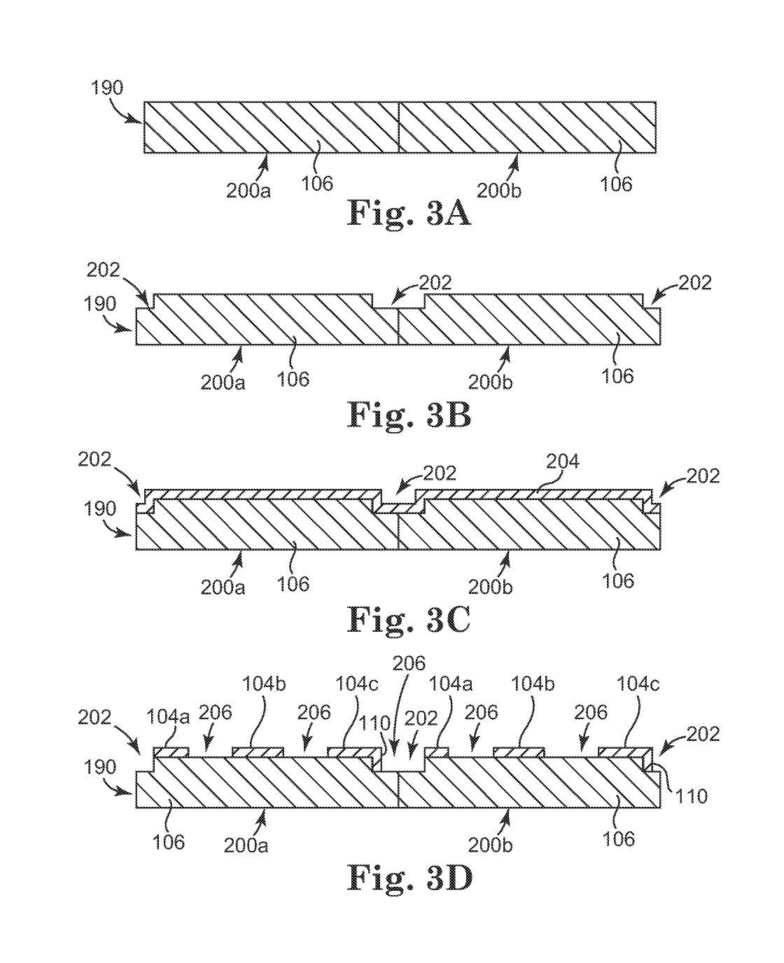

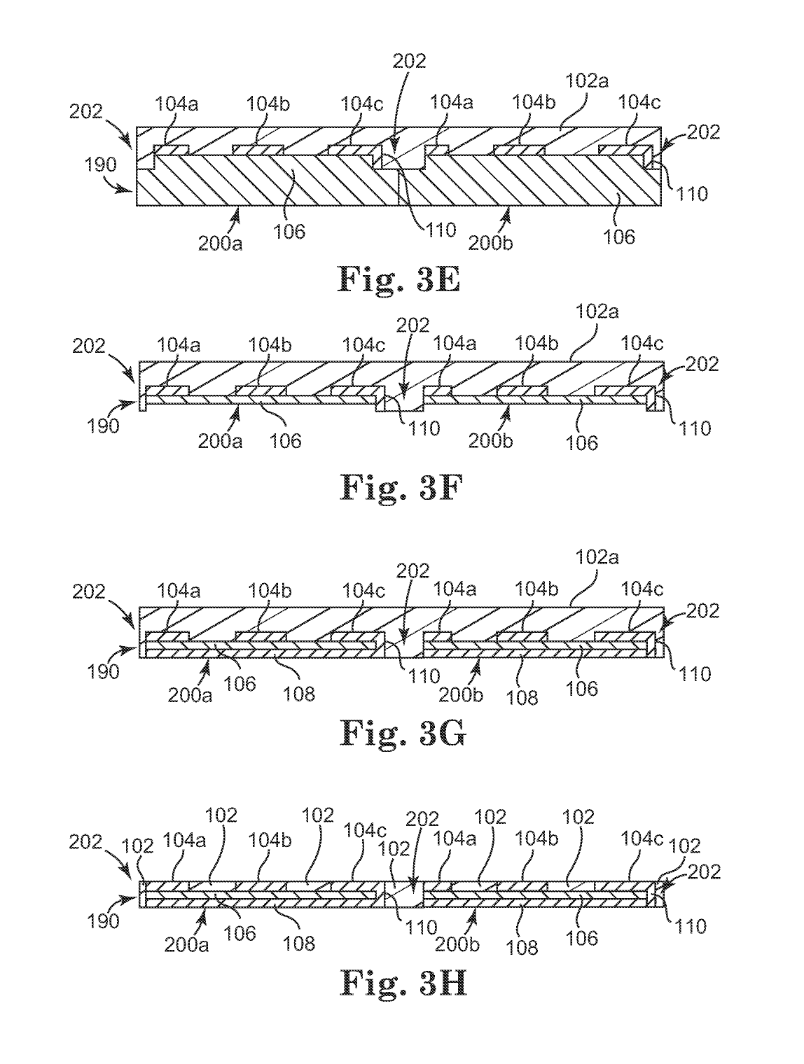

FIGS. 3A-3H illustrate one embodiment of a method for fabricating a semiconductor device including wafer level encapsulation, such as semiconductor device 100 previously described and illustrated with reference to FIG. 1.

FIG. 3A illustrates a cross-sectional view of one embodiment of a semiconductor wafer 190. The semiconductor wafer 190 includes two dies 200a and 200b. Each die 200a and 200b includes an active area 106. Each active area 106 includes transistors, diodes, or other suitable devices formed in a silicon substrate or other suitable substrate.

FIG. 3B illustrates a cross-sectional view of one embodiment of the semiconductor wafer 190 after etching trenches 202 into the semiconductor wafer. In one embodiment, photolithography or other suitable lithographic process is used to pattern trenches 202 between dies 200a and 200b for etching. Active areas 106 are etched to provide trenches 202, which provide sawing streets for separating dies 200a and 200b in a later processing step. In another embodiment, trenches 202 are formed by sawing. The trenches 202 facilitate singulation of the individual dies 200a and 200b.

FIG. 3C illustrates a cross-sectional view of one embodiment of the semiconductor wafer 190 after depositing a frontside metal layer 204 on the frontside surface of wafer 190. A metal, such as W, Al, Ti, Ta, Cu, or other suitable metal is deposited over active areas 106 and trenches 202 to provide frontside metal layer 204. Frontside metal layer 204 is deposited using CVD, atomic layer deposition (ALD), metal organic chemical vapor deposition (MOCVD), plasma vapor deposition (PVD), jet vapor deposition (JVD), or other suitable deposition technique.

FIG. 3D illustrates a cross-sectional view of one embodiment of the semiconductor wafer 190 after etching frontside metal layer 204. Photolithography or other suitable lithographic process is used to pattern openings 206 for etching. Frontside metal layer 204 is etched to provide openings 206 exposing portions of active areas 106 and to provide frontside metal contacts 104a-104c and metal interconnection structures 110.

FIG. 3E illustrates a cross-sectional view of one embodiment of the semiconductor wafer 190 after depositing a packaging material layer 102a. A packaging material, such as a plasmapolymer, amorphous inorganic or ceramic carbon, or other suitable packaging material is deposited over exposed portions of active areas 106 and frontside metal contacts 104 to provide packaging material layer 102a. Packaging material layer 102a is deposited using gas phase deposition, such as CVD. In one embodiment, packaging material layer 102a is deposited at room temperature.

In one embodiment, the gas phase deposited packaging materials are generated from evaporated organic molecules. The properties of the deposited packaging materials are determined by the type of organic precursors, the process parameters, and the flow of used oxygen, hydrogen, or other suitable gas during the deposition. Typical deposited layers can be parylenes (e.g., plasmapolymer with hydrogen content in the polymer backbone and therefore a relatively low flexural modulus), amorphous carbon layers (with a CTE close to silicon), or diamond like carbon (DCL), if the used gas precursors are simple hydrocarbon molecules and the added oxygen flow is high. According to the specific uses for the packaging material, coating, or encapsulant, a broad variety of material properties can be adjusted by the described gas phase processes.

In addition to encapsulating and protecting the active areas 106 of the wafer 190, packaging material layer 102a acts as a wafer level carrier that provides support during thinning of wafer 190, and simplifies the handling of the thinned wafer.

FIG. 3F illustrates a cross-sectional view of one embodiment of the semiconductor wafer 190 after thinning the wafer backside. The backside of active areas 106 is thinned by grinding and etching to provide thinned active areas 106. In one embodiment, the wafer backside is thinned at least until the bottom of the trenches 202 are reached, thereby exposing the bottom portion of the metal interconnection structures 110.

FIG. 3G illustrates a cross-sectional view of one embodiment of the semiconductor wafer 190 after depositing backside metal contacts 108. A metal, such as W, Al, Ti, Ta, Cu, or other suitable metal is deposited over active areas 106 to provide metal contacts 108. In one embodiment, the metal is planarized to remove any overshoot and to expose packaging material 102a. The metal is planarized using chemical mechanical polishing (CMP) or another suitable planarization technique. The metal contacts 108 are each in contact with a metal interconnection structure 110, which connects the metal contacts 108 to frontside metal contacts 104c.

In another embodiment, the structures 108 are configured as heat sinks or heat spreaders. In this embodiment, the structures 108 facilitate heat transfer out of the devices. When configured as a heat sink according to one embodiment, any suitable material with appropriate thermal conductivity may be used for structure 108.

FIG. 3H illustrates a cross-sectional view of one embodiment of the semiconductor wafer 190 after thinning the packaging material layer 102a. Packaging material layer 102a is thinned using CMP or another suitable planarization technique to expose frontside metal contacts 104 and provide packaging material layer 102. In one embodiment, solder balls are then applied to frontside metal contacts 104 to provide a semiconductor wafer similar to semiconductor wafer 150 previously described and illustrated with reference to FIG. 2A.

Dies 200a and 200b are then separated by sawing through packaging material 102 at the trenches 202 to provide semiconductor devices similar to semiconductor device 100 previously described and illustrated with reference to FIG. 1. If desired, dies 200a and 200b can be further packaged using a mould process, for example.

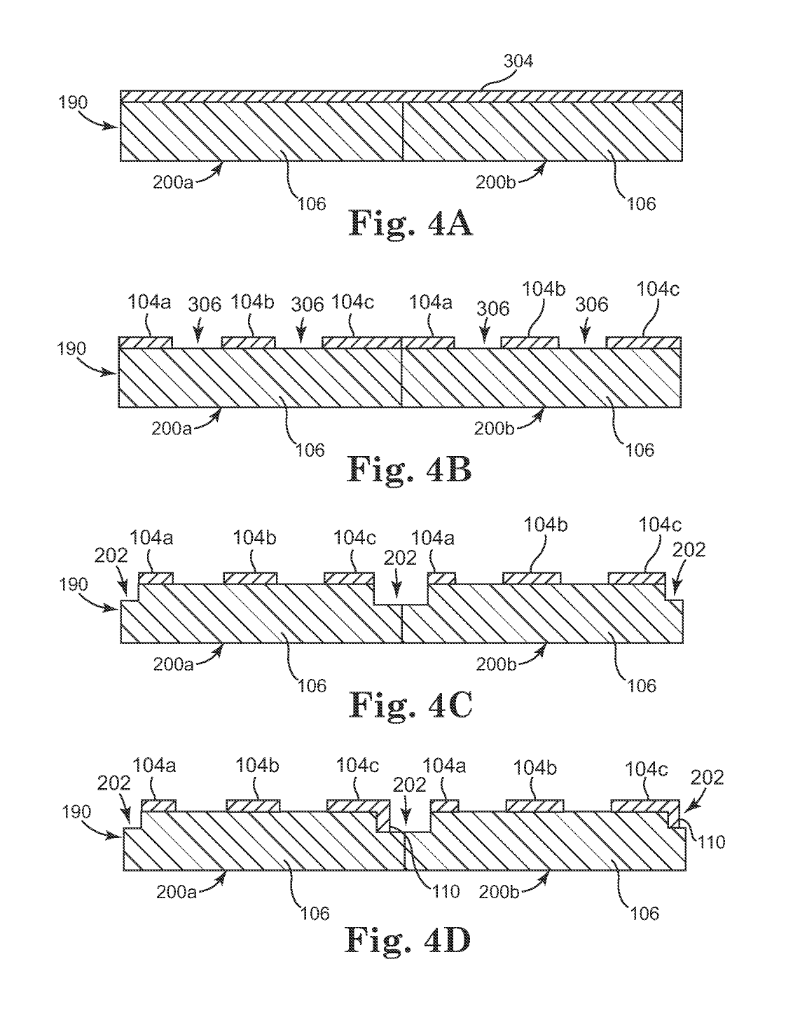

FIGS. 4A-4D illustrate another embodiment of a method for fabricating a semiconductor device including wafer level encapsulation, such as semiconductor device 100 previously described and illustrated with reference to FIG. 1.

FIG. 4A illustrates a cross-sectional view of one embodiment of semiconductor wafer 190 after depositing a frontside metal layer 304 on the frontside surface of wafer 190. A metal, such as W, Al, Ti, Ta, Cu, or other suitable metal is deposited over active areas 106 to provide frontside metal layer 304. Frontside metal layer 304 is deposited using CVD, atomic layer deposition (ALD), metal organic chemical vapor deposition (MOCVD), plasma vapor deposition (PVD), jet vapor deposition (JVD), or other suitable deposition technique.

FIG. 4B illustrates a cross-sectional view of one embodiment of the semiconductor wafer 190 after etching frontside metal layer 304. Photolithography or other suitable lithographic process is used to pattern openings 306 for etching. Frontside metal layer 304 is etched to provide openings 306 exposing portions of active areas 106 and to provide frontside metal contacts 104a-104c.

FIG. 4C illustrates a cross-sectional view of one embodiment of the semiconductor wafer 190 after etching trenches 202 into the semiconductor wafer. Photolithography or other suitable lithographic process is used to pattern trenches 202 between dies 200a and 200b for etching. Contacts 104 and active areas 106 are etched to provide trenches 202, which provide sawing streets for separating dies 200a and 200b in a later processing step.

FIG. 4D illustrates a cross-sectional view of one embodiment of the semiconductor wafer 190 after forming metal interconnection structures 110 in the trenches 202. A metal, such as W, Al, Ti, Ta, Cu, or other suitable metal is deposited on one wall of each trench 202 to provide metal interconnection structures 110. Metal interconnection structures 110 are deposited using CVD, atomic layer deposition (ALD), metal organic chemical vapor deposition (MOCVD), plasma vapor deposition (PVD), jet vapor deposition (JVD), or other suitable deposition technique. Photolithography or other suitable lithographic process is used to provide an appropriate pattern for the deposition of the interconnection structures 110.

In one embodiment, after the metal interconnection structures 110 are formed as shown in FIG. 4D, the wafer 190 is further processed as shown in FIGS. 3E-3H (and described above with reference to these Figure), including forming a packaging material layer 102a, thinning the wafer backside, depositing backside metal contacts 108, and thinning the packaging material layer 102a. After the deposition shown in FIG. 3G and described above, the metal contacts 108 are each in contact with a metal interconnection structure 110, which connects the metal contacts 108 to frontside metal contacts 104c.

After the thinning of the packaging material layer 102a shown in FIG. 3H and described above, in one embodiment, solder balls are then applied to frontside metal contacts 104 to provide a semiconductor wafer similar to semiconductor wafer 150 previously described and illustrated with reference to FIG. 2A. Dies 200a and 200b are then separated by sawing through packaging material 102 at the trenches 202 to provide semiconductor devices similar to semiconductor device 100 previously described and illustrated with reference to FIG. 1. If desired, dies 200a and 200b can be further packaged using a mould process, for example.

Embodiments of the present invention provide semiconductor devices encapsulated at the wafer level. A packaging material is deposited on a semiconductor wafer using gas phase deposition to encapsulate the active areas of the wafer. In addition, embodiments of the present invention provide a wafer level carrier to provide support during thinning of wafers and to simplify the handling of thinned wafers. A thick layer of packaging material is deposited on the semiconductor wafer using gas phase deposition to provide support for backside grinding and etching and for handling the thinned wafer after backside grinding and etching. Metal interconnection structures are formed at the wafer level to connect a backside contact of each die to a frontside contact of the die.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a substrate including an active area;
a first metal contact contacting a frontside of the active area;
a second metal contact contacting a backside of the active area; and
a wafer-level deposited metal structure positioned adjacent to an edge of the active area and interconnecting the first and second contacts.

2. The integrated circuit of claim 1, and further comprising
packaging material encapsulating the active area and the metal structure.

3. The integrated circuit of claim 2, wherein the first metal contact extends through the packaging material.

4. The integrated circuit of claim 1, wherein the substrate comprises a thinned substrate.

5. The integrated circuit of claim 1, wherein the metal structure is deposited at the wafer level in a trench formed in a frontside of a wafer.

6. The integrated circuit of claim 5, wherein the trench is configured to facilitate singulation of the integrated circuit.

7. The integrated circuit of claim 5, wherein the metal structure is exposed to a backside of the wafer by thinning a backside of the wafer.

8. The integrated circuit of claim 1, wherein the integrated circuit includes a vertical power transistor, and wherein the first metal contact is a drain contact for the transistor.

9. The integrated circuit of claim 8, wherein the integrated circuit further comprises:
a source contact for the transistor contacting a frontside of the active area; and
a gate contact for the transistor contacting a frontside of the active area.

10. A semiconductor wafer comprising:
a substrate including a plurality of dies, each die including an active area; and
a plurality of metal structures, each metal structure deposited adjacent to an edge of one of the dies and connecting a frontside metal contact of the die to a backside metal contact of the die.

11. The semiconductor wafer of claim 10, and further comprising:
a plurality of frontside metal contacts, each of the frontside metal contacts contacting a frontside of one of the dies; and
a plurality of backside metal contacts, each of the backside metal contacts contacting a backside of one of the dies.

12. The semiconductor wafer of claim 10, and further comprising
packaging material encapsulating the active area of each die and the metal structures.

13. The semiconductor wafer of claim 12, wherein a frontside metal contact of each die extends through the packaging material.

14. The semiconductor wafer of claim 10, wherein the substrate comprises a thinned substrate.

15. The semiconductor wafer of claim 10, wherein the metal structures are deposited in trenches formed in a frontside of the substrate.

16. The semiconductor wafer of claim 15, wherein the trenches are configured to facilitate singulation of the plurality of dies.

17. The semiconductor wafer of claim 15, wherein the metal structures are exposed to a backside of the substrate by thinning a backside of the substrate.

18. A method for processing a semiconductor wafer that includes a plurality of dies, each die including an active area, the method comprising:
forming trenches in a frontside of the wafer between the dies; and
forming a metal structure in each of the trenches, thereby forming a plurality of metal structures for interconnecting a frontside metal contact of each die to a backside metal contact of each die.

19. The method of claim 18, and further comprising:
thinning a backside of the wafer, thereby exposing a portion of each of the metal structures to the backside of the wafer.

20. The method of claim 19, and further comprising:
forming a plurality of backside metal contacts on the backside of the wafer, each backside metal contact in contact with the exposed portion of one of the metal structures.

21. The method of claim 18, and further comprising:
depositing a metal layer on a frontside of the wafer; and
etching the metal layer at selected locations, thereby forming at least one frontside metal contact for each die and the plurality of metal structures.

22. The method of claim 18, and further comprising:
depositing a packaging material over the wafer to encapsulate the active area of each die and the metal structures.

23. The method of claim 18, wherein the trenches facilitate singulation of the dies.
